(19) United States
(12) Patent Application Publication
(10) Pub. No.: US 2010/0068408 A1
(43) Pub. Date: Mar. 18, 2010

(54) METHODS FOR ELECTRON-BEAM INDUCED DEPOSITION OF MATERIAL INSIDE ENERGETIC-BEAM MICROSCOPES

(75) Inventors: Lyudmila Zaykova-Feldman, Dallas, TX (US); Rocky Kruger, Dallas, TX (US); Thomas M. Moore, Dallas, TX (US); Herschel M. Marchman, Dallas, TX (US)

Correspondence Address: Glast, Phillips & Murray, P.C, 13355 Noel Road, Suite 2200, Dallas, TX, 75240, US

(73) Assignee: Omniprobe, Inc., Dallas, TX (US)

(21) Appl. No.: 12/211,638

(22) Filed: Sep. 16, 2008

(51) Int. Cl. C23C 16/46; C23C 16/02

(52) U.S. Cl. 427/532; 427/585

(57) ABSTRACT

We disclose method for materials deposition on a surface inside an energetic-beam instrument, where the energetic beam instrument is provided with a laser beam, an electron beam, and a source of precursor gas. The electron beam is focused on the surface, and the laser beam is focused to a focal point that is at a distance above the surface of about 5 microns to one mm, preferably from 5 to 50 microns. The focal point of the laser beam will thus be within the stream of precursor gas injected at the sample surface, so that the laser beam will facilitate reactions in this gas cloud with less heating of the surface. A second laser may be used for cleaning the surface.

### CO-PENDING APPLICATION

This application is related to co-pending application Ser. No. 12/201,447, filed Sep. 4, 2008, titled “Single-channel optical processing system for energetic-beam microscopes,” which application is incorporated by reference into the present application.

### BACKGROUND

1. Technical Field

This disclosure relates to systems and methods for the deposition of materials upon surfaces and structures inside energetic-beam microscopes, such as the inspection and edit of integrated circuits, semiconductor wafers and photolithographic masks.

2. Background Art

Current editing processes for microscopic structures, such as integrated circuit chips (ICs) and photolithographic masks generally rely on the formation of local areas of energy dissipation on the surfaces thereof to cause locally confined endothermic reactions. These reactions allow for selective deposition or etching of materials.

Focused ion-beam (FIB) tools have become dominant in most edit applications, as well as for specimen extraction for failure analysis of IC's. Although laser induced reactions are not confined as well as those from FIB, lasers have far superior reaction rates, compared to focused ion beams. Electron beams usually cause reactions that have slower rates, but with much better confinement than that of FIBs. Issues of damage and contamination are currently being encountered more often during FIB imaging and processing of new materials developed for fabrication of ICs. Thus, it is becoming more important to consider use of both laser and electron beams for edit applications.

Electron-beam induced deposition (EBID) and etch are the editing methods having the most attention in related industry and research. The use of a laser beam together with the electron beam presents an opportunity to speed up the reaction in the area of interest, by both pyrolytic and photolytic effects, to monitor the process, and to enhance the deposition and etch processes. The laser beam improves the dissociation process of the precursor gas used. It is known that changing the temperature of the sample surface being processed significantly affects reaction rates. For the deposition process, the rate of growth of deposited material can be improved by lowering the surface temperature. For the etch process, the rate of removal of material from the surface can be improved by increasing the temperature of the surface being modified.

There is a need for a method to speed up the deposition processes promoted by the electron beam, and leave fewer contamination materials on the surface, while also allowing the operator to view a sample in the process chamber at the same time as processing takes place.

### DRAWINGS

FIG. 1 is a schematic depiction of imaging of an area of interest on a sample surface.

FIG. 2 is a schematic depiction of electron-beam induced deposition according to the preferred embodiment.

FIG. 3 is a schematic depiction of application of a second laser beam to clean a surface before or after electron-beam induced deposition.

FIG. 4 is a flowchart for an embodiment of the EBID method.

FIG. 5 is a graph representing the EBID cycles of an embodiment.

FIG. 6 is a perspective view of a single-channel optical processing system located inside the chamber of an energetic beam instrument and used for the EBID.

### DESCRIPTION

In this disclosure, the term “light” should be taken to refer to electromagnetic radiation in general, although the wavelengths employed may or may not fall with in the range of human vision. Unless otherwise specified, the term “light” is used interchangeably with the term “radiation.”

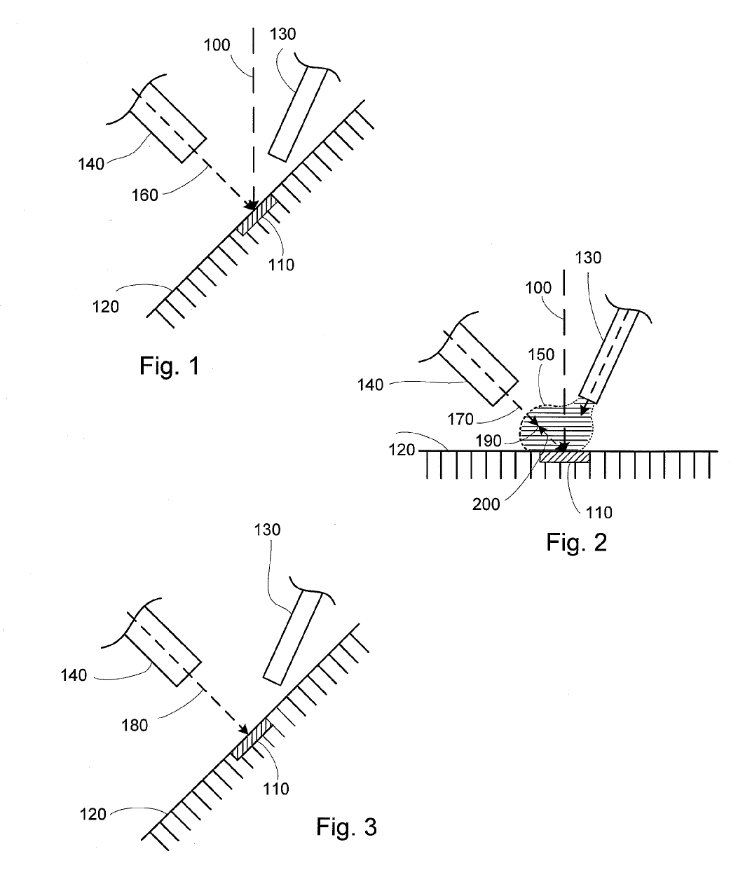

FIG. 1 shows schematically a sample surface (120) inside an energetic-beam microscope, with an area of interest (110) positioned beneath the electron beam (100). A gas injector (130) is positioned near the area of interest (110) to selectively deliver a flow of precursor gas (150) to the sample surface (120). A beam of illumination light (160) for imaging falls upon the surface (120). The sample surface (120) is shown inclined from the horizontal so that the illumination light (160) is normal to the surface.

It is known that the EBID process benefits from cooling the surface (120) where the deposition takes place. Typically, the surface (120) is cooled by either cooling the entire stage, by a cold finger, such as the Cryocooler model LSF 9580, manufactured by Thales Cryogenics, or by attaching local Peltier elements to the bottom side of the sample surface (120) (using, for an instance, an EMITECH K25X Peltier cooling stage). The prior-art practice of focusing a laser beam onto a surface, however, tends to retard the deposition process because of the hot spot created by the laser energy.

FIG. 2 shows an embodiment of our method. Here, after imaging, the sample surface (120) is returned to the horizontal so as to be normal to the electron beam (100), which is preferable. A precursor gas system, such as the OmniGIS™ manufactured by Omniprobe, Inc. of Dallas, Tex., delivers a stream of precursor gas (150) to the surface (120). A laser beam (170) is directed toward the area of interest (110) but in this case the laser beam (170) is brought to a focal point (190) at a distance (200) above the sample surface (120). Most dissociation of gas molecules by the laser energy takes place in the stream of gas (150) above the sample surface (120), and the surface itself (120) is not heated substantially by the laser energy. Thus, deposition reactions can thus proceed faster. The distance (200) of the focal point (190) of the processing laser light (170) should be sufficiently close to the surface for reaction products originating in the gas phase to reach the surface (120). This distance would be about 5 microns up to about one mm, depending on the type of gas delivery system and the working distance of the optical system used. If a gas injector like the OmniGIS™ is used, the preferable interval can be from about 5 microns to about 50 microns.

The focal point (190) of the laser light (170) can be moved by adjusting an external optical system or by raising and lowering the stage holding the sample (120). It is preferable to use the OptoProbe™ single-channel optical system, made by Omniprobe, Inc. of Dallas, Tex. This system allows illumination light (160) and one or more laser beams (170, 180) to be directed through a single optical channel (140) and focused together on an area of interest (110).

Many times it is desirable to use different wavelengths of laser light for either a pyrolytic effect or a photolytic effect. Also, a different wavelength of laser light, usually in the UV, can be used for cleaning a surface. One could also employ IR or visible wavelengths to achieve cleaning through thermal desorption of undesired surface contaminants. Note that the focal point of the cleaning laser energy would generally be at the surface (120), so the optical system must be adjusted to accommodate the shift in focal point. A single-channel optical system (140) achieves this flexibility, since only one port of the microscope need be used for multiple laser sources.

FIG. 3 shows the sample surface (120) undergoing cleaning before or after deposition. The gas injector (130) is shut off A cleaning laser beam (180), optionally from a second laser, is directed onto the sample surface (120).

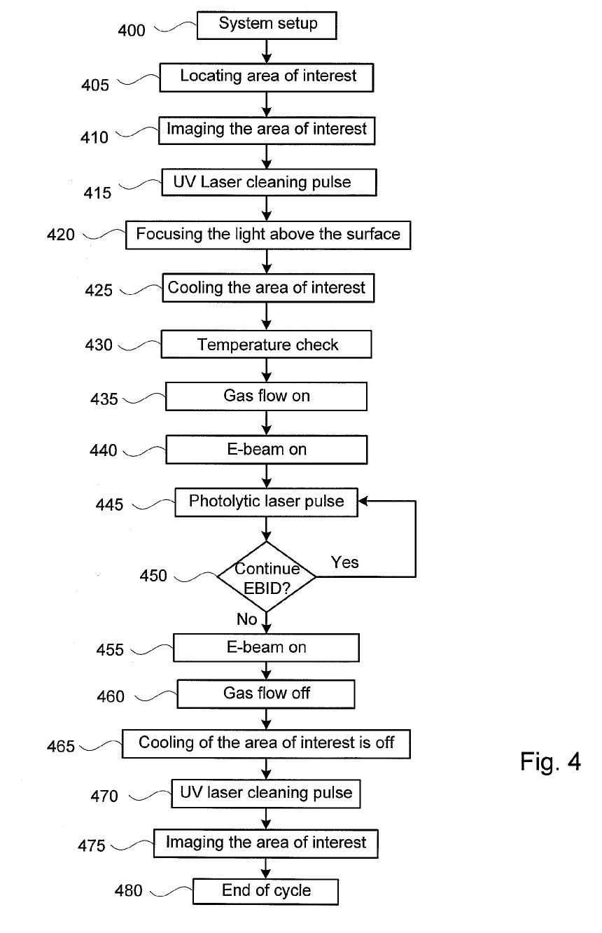

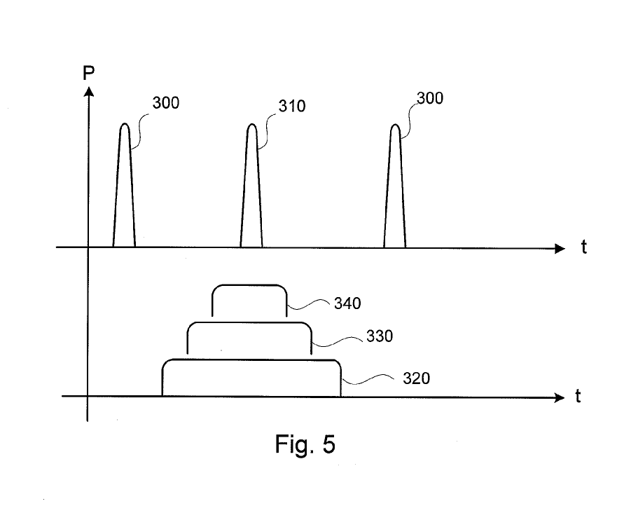

FIG. 4 is a flowchart presenting a sequence of operations for the EBID process according to the present invention. FIG. 5 is a graph showing relative durations of the various process parameters. These parameters are the cleaning laser pulses (300), processing laser pulses (310), stage cooling (320), gas flow (330) and electron-beam application (340). The graph in FIG. 5 is not to scale.

At step 400, the system is set up with the specimen loaded into the microscope chamber and the specimen stage inclined at the desired angle. At the next step 405, the area of interest (110) is located at the surface (120) by any means known in the art, such as coordinate calculations or scanning the area and finding special markings. After the area of interest (110) is identified, it is imaged at step 410 and cleaned from already existing contamination by a short laser pulse (300) at step 415. An ultraviolet laser beam, having a wavelength in the region from 190 nm to 400 nm, can be used for this purpose, or, one can also clean thermally using IR or visible light to heat the surface (120). The area of interest can be optionally imaged again if desired to confirm cleaning.

The processing laser light (170) is focused above the sample surface (120) as discussed above at step 420. The area of interest is cooled down at step 425. The cooling process (320) requires some time (usually of the order of several minutes) for temperature stabilization, so it can be optionally started earlier. If a Peltier stage is used, the temperature to which the surface (120) should be cooled can be pre-set. If other means like cold fingers are used, there can be an optional temperature check at step 430.

The gas flow (330) starts at step 435, followed by the electron beam introduction (340) at step 440 and photolytic laser pulse (310) at step 445. There can be a single laser pulse (310) and a simultaneous e-beam pulse (340), or a series of these pulses, not necessarily simultaneous, depending on the desired thickness of the deposited material desired and the precursor chemistry, as chosen in step 450. If deposition is finished at step 455, the electron beam is turned off and the gas flow (150) is stopped at step 460. If there are no other depositions planned, the cooling of the sample surface (120) can be turned off at step 465. Hydrocarbon deposits and other surface contaminants can be cleaned off at the next step 470 with a laser cleaning pulse (300), and the area of interest (110) can be imaged again at step 475 to monitor the progress visually. The deposition cycle ends at step 480.

Depending on the incident flux of the precursor gas (150) from the injection nozzle (130), the electron-beam induced deposition process can be performed as a two-step process. The first step is a process described above, where the sample surface (120) is cleaned by a first pulse (300), processed by second pulses (310) while cooled, and then cleaned again by a second cleaning pulse (300). Contamination deposits of non-carbon nature can also be cleaned by heating the sample surface (120) instead of using additional laser pulses (310). Hence, the first processing step can be followed with a short waiting period to allow the chemical reaction process to be finished. After this waiting period, heat can be applied, using a heated sample stage or, for an instance, the previously mentioned thermoelectric Peltier elements.

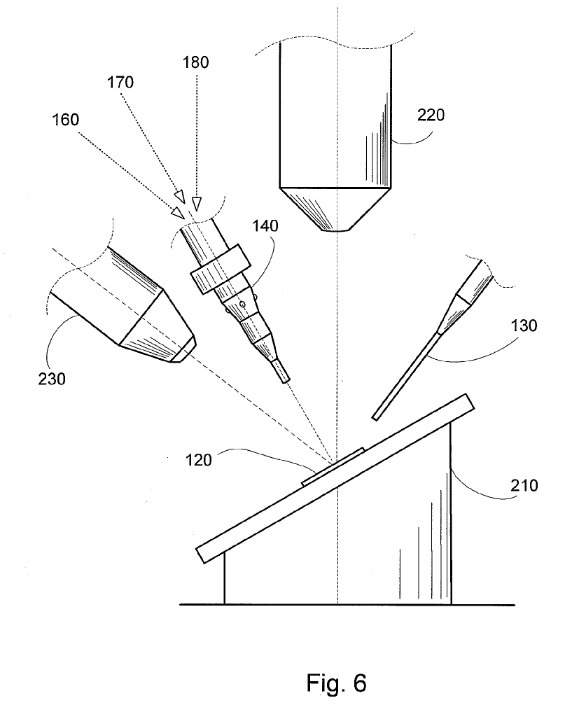

FIG. 6 is a perspective view of the several component instruments typically required for EBID inside an energetic beam instrument, showing the relative location of a stage (210) for holding a sample (120). A typical orientation of the electron beam column (220) and the ion beam column (230) is shown. FIG. 6 illustrates generally that a single-channel optical processing system (140) allows combined processing and imaging light to be provided in confined space typical of energetic beam instruments without physically interfering with the electron beam column (220), the ion beam column (230), or a gas injector (130). FIG. 6 also shows schematically the multiplexing of illumination light (160), first laser light (170) and second laser light (180) in the single optical channel (140). The setup shown as an example in FIG. 6 is a typical setup of a Zeiss FIB, and will vary somewhat with FIBs from different manufacturers.

We claim:

1. A method for materials deposition on a surface inside an energetic-beam: instrument, where the energetic beam instrument comprises a laser beam, an electron beam, and a source of precursor gas; the method comprising:
focusing the electron beam on the surface;
focusing the laser beam to a focal point at a distance above the surface;
injecting the precursor gas near the surface,
so that the precursor gas forms a stream including the focal point of the laser beam;
applying one or more pulses of the laser beam;
applying one or more pulses of the electron beam.

2. The method of claim 1 where the one or more electron-beam pulses are applied at substantially the same time as the one or more pulses of the laser beam.

3. The method of claim 1 further comprising:
cooling the surface before applying the pulses of the laser beam and the electron beam.

4. The method of claim 1, where the distance above the surface is in the range of about 5 microns to about one mm.

5. The method of claim 1, where the distance above the surface is in the range of about 5 microns to about 50 microns.

6. The method of claim 1 where the laser beam has a wavelength capable of causing photolytic dissasociation of the precursor gas.

7. The method of claim 1, further comprising:
applying one or more laser pulses to the surface for cleaning the surface before injecting the precursor gas.

8. The method of claim 6, where the one or more laser pulses applied to the surface before injecting the precursor gas are emitted from a second laser.

9. The method of claim 1, further comprising:
stopping the injection of the precursor gas after applying the one or more laser pulses and the one or more electron beam pulses; and,
applying one or more laser pulses to the surface for cleaning the surface after stopping the injection of the precursor gas.

10. The method of claim 9, where the one or more laser pulses applied to the surface after stopping the injection of the precursor gas are emitted from a second laser.

11. A method for materials deposition on a surface inside an energetic-beam instrument, where the energetic beam instrument comprises a laser beam, a second laser beam, an electron beam, and a source of precursor gas; the method comprising:
focusing the electron beam on the surface;
focusing the first laser beam to a focal point at in the range of about 5 microns to about one mm above the surface;
where the first laser beam has a wavelength capable of causing photolytic dissasociation of the precursor gas;
applying one or more laser pulses from the second laser beam to the surface for cleaning the surface before injecting the precursor gas;
cooling the surface;
injecting the precursor gas near the surface,
so that the precursor gas forms a stream including the focal point of the first laser beam;
applying one or more pulses of the first laser beam;
applying one or more pulses of the electron beam.

12. The method of claim 10, where the one or more electron-beam pulses are applied at substantially the same time as the one or more pulses of the first laser beam.
